(19) United States
(12) Patent Application Publication
(10) Pub. No.: US 2025/0336046 A1
(43) Pub. Date: Oct. 30, 2025

(54) SYSTEM AND METHOD FOR DISTORTION ADJUSTMENT DURING INSPECTION

(71) Applicant: ASML Netherlands B.V., Veldhoven (NL)

(72) Inventors: Peter Oliver SPRAU, Los Altos, CA (US); Victor Emanuel CALADO, Rotterdam (NL); Hermanus Adrianus DILLEN, Maarheeze (NL); Chi-Hsiang FAN, Morgan Hill, CA (US); Michael D. LU, Cupertino, CA (US); Wim Tjibbo TEL, Veldhoven (NL); Willem Louis VAN MIERLO, Helmond (NL); Yun- Ling YEH, San Jose, CA (US); Weihua YIN, San Jose, CA (US); Yi-Hsien YU, San Jose, CA (US); Yan SUN, San Jose, CA (US); Marc Jurian KEA, Morgan Hill, CA (US)

(73) Assignee: ASML Netherlands B.V., Veldhoven (NL)

(21) Appl. No.: 18/867,001

(22) PCT Filed: May 4, 2023
(86) PCT No.: PCT/EP2023/061789

§ 371 Date: Nov. 18, 2024

Related U.S. Application Data
(60) Provisional application No. 63/347,984, filed on Jun. 1, 2022.
(60) Provisional application No. 63/456,628, filed on Apr. 3, 2023.

(51) Int. Cl. G06T 5/80; G06T 5/50; G06T 7/00; G06T 7/33

(52) U.S. Cl. CPC G06T 5/80; G06T 5/50; G06T 7/0004; G06T 7/337; G06T 2207/10061; G06T 2207/30148

(57) ABSTRACT

Systems, apparatuses, and methods for adjusting distortion in images. Embodiments include obtaining a plurality of images; determining alignment differences between a plurality of features on the plurality of images and corresponding features in layout data corresponding to the plurality of images; modeling the alignment differences; and adjusting at least one of: a machine setting corresponding to obtaining the plurality of images; or at least one feature of the plurality of features on at least one image of the plurality of images using the modeling.

### CROSS-REFERENCE TO RELATED APPLICATIONS

This application claims priority of U.S. application 63/347,984 which was filed on 1 Jun. 2022 and U.S. application 63/456,628 which was filed on 3 Apr. 2023 and which are incorporated herein in their entirety by reference.

### FIELD

The description herein relates to the field of inspection systems, and more particularly to systems for adjusting distortion in images during inspection.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused at locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide apparatuses, systems, and methods for adjusting distortion in images. In some embodiments, systems, methods, and non-transitory computer readable mediums may include obtaining a plurality of images; determining alignment differences between a plurality of features on the plurality of images and corresponding features in layout data corresponding to the plurality of images; modeling the alignment differences; and adjusting at least one of: a machine setting corresponding to obtaining the plurality of images; or at least one feature of the plurality of features on at least one image of the plurality of images using the modeling.

In some embodiments, systems, methods, and non-transitory computer readable mediums may include obtaining a first plurality of images at a first machine setting; determining first alignment differences between a plurality of features on the first plurality of images and corresponding features in layout data corresponding to the first plurality of images; modeling the first alignment differences using a first modeling; determining at least one metrology error associated with the first alignment differences; determining a second machine setting based on the at least one metrology error; obtaining a second plurality of images at the second machine setting; determining second alignment differences between a plurality of features on the second plurality of images and corresponding features in layout data corresponding to the second plurality of images; modeling the second alignment differences using a second modeling; and adjusting at least one of: the second machine setting; or at least one feature of the plurality of features on at least one image of the second plurality of images using the second modeling.

In some embodiments, systems, methods, and non-transitory computer readable mediums may include obtaining a plurality of images; determining a plurality of position coordinates, where each position coordinate of the plurality of position coordinates corresponds to a feature of a plurality of features on the plurality of images; determining a plurality of differences, where each difference of the plurality of differences is between each position coordinate of the plurality of position coordinates and a predetermined position coordinate of a plurality of predetermined position coordinates corresponding to the plurality of features; modeling the plurality of differences; and adjusting at least one of: a machine setting corresponding to obtaining the plurality of images; or at least one position coordinate corresponding to a feature of the plurality of features using the modeling.

### BRIEF DESCRIPTION OF THE DRAWINGS

FIG. 1 is a schematic diagram illustrating an exemplary electron beam inspection (EBI) system, consistent with embodiments of the present disclosure.

FIG. 2 is a schematic diagram illustrating an exemplary multi-beam system that is part of the exemplary charged particle beam inspection system of FIG. 1, consistent with embodiments of the present disclosure.

FIG. 3 is schematic diagram illustrating an exemplary configuration of control circuitry associated with segmented charged-particle beam deflectors, consistent with embodiments of the present disclosure.

FIG. 4 is a schematic diagram of an exemplary system for adjusting distortion in images, consistent with embodiments of the present disclosure.

FIG. 5 is a schematic diagram illustrating an exemplary alignment of an image of an area of a sample with corresponding layout data, consistent with embodiments of the present disclosure.

FIG. 6 is a flowchart illustrating an exemplary process of adjusting distortion in images, consistent with embodiments of the present disclosure.

FIG. 7 is a schematic diagram illustrating exemplary images of areas of a sample with corresponding layout data, consistent with embodiments of the present disclosure

FIG. 8 is a flowchart illustrating an exemplary process of adjusting distortion in images, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like, in which they generate corresponding types of images.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly and also if it was formed at the proper location. If the structure is defective, then the process can be adjusted so the defect is less likely to recur. Defects may be generated during various stages of semiconductor processing. For the reason stated above, it is important to find defects accurately and efficiently as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

During inspection, it is advantageous to generate images (e.g., SEM images, optical images, x-ray images, photon images, etc.) with reduced distortion so that the features (e.g., contact holes, a metal line, a gate, etc.) on a sample in the images accurately represent the actual sample. In order to generate images with reduced distortion, images may be adjusted or modified to correct for distortions of features in the images.

In typical inspection systems, distortions in images may be characterized by and corrected for using polynomial expressions. In typical inspection systems, distortions in images may be corrected such that the standard deviation (“a”) of the distortion is below a threshold (e.g., such that 3σ is less than a threshold value of distortion).

Typical systems with distortion control, however, suffer from constraints. An example of a constraint with typical systems is that they may only effectively correct distortions that may be characterized by lower order polynomial expressions (e.g., first order polynomial expressions, second order polynomial expressions, or third order polynomial expressions). Lower order polynomial expressions may not accurately characterize some types of distortion. Instead, higher order distortions are accurately characterized by higher order polynomial expressions (e.g., polynomial expressions greater than third order). For example, higher order distortions may be created by digital to analog converters (“DACs”) that control deflectors in an inspection system. Lower order polynomial expressions may not correct for higher order distortions (e.g., the distortion threshold may be 3σ<0.18 nm, but using lower order polynomial expressions to correct for higher order distortions may result in 3σ=0.70 nm) such that the features on a sample in the images do not accurately represent the actual sample.

Some of the disclosed embodiments provide systems and methods that address some or all of these disadvantages by adjusting images for higher order distortions during inspection. The disclosed embodiments may determine alignment or position differences between features in an image and corresponding features in layout data, model the differences using a higher order model, and adjust the spatial position of pixels in the image using the modeling, thereby correcting for higher order distortions in an image of a sample.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

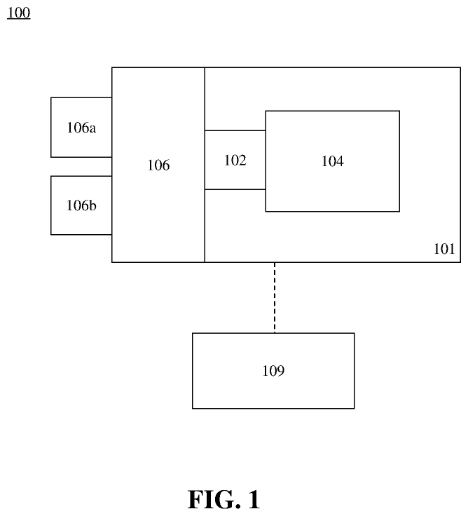

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

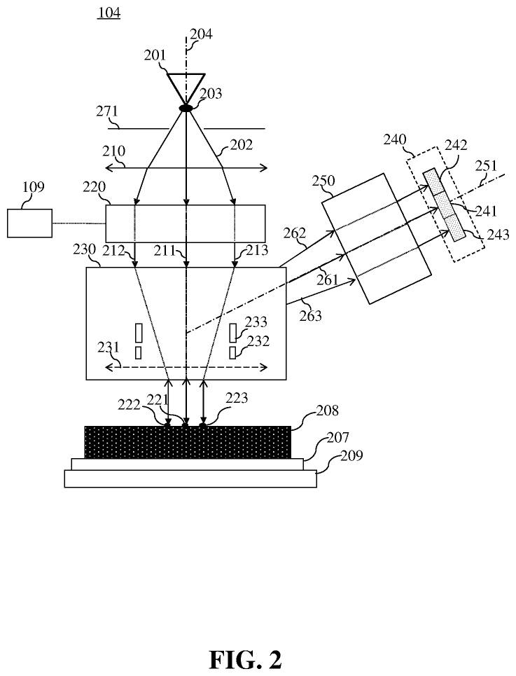

Reference is now made to FIG. 2, which is a schematic diagram illustrating an exemplary electron beam tool 104 including a multi-beam inspection tool that is part of the EBI system 100 of FIG. 1, consistent with embodiments of the present disclosure. In some embodiments, electron beam tool 104 may be operated as a single-beam inspection tool that is part of EBI system 100 of FIG. 1. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiments, apparatus 104 may be operated as a single-beam system such that a single primary beamlet is generated. In some embodiments, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2 shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principle plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy ≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 over time depending on the steps of scanning process.

Although FIG. 2 shows that apparatus 104 uses three primary electron beams, it is appreciated that apparatus 104 may use one, two, or more number of primary electron beams. The present disclosure does not limit the number of primary electron beams used in apparatus 104. In some embodiments, apparatus 104 may be a SEM used for lithography. In some embodiments, electron beam tool 104 may be a single-beam system or a multi-beam system.

Embodiments of this disclosure may provide a single charged-particle beam imaging system (“single-beam system”). Compared with a single-beam system, a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries and adapting to different throughputs and resolution requirements.

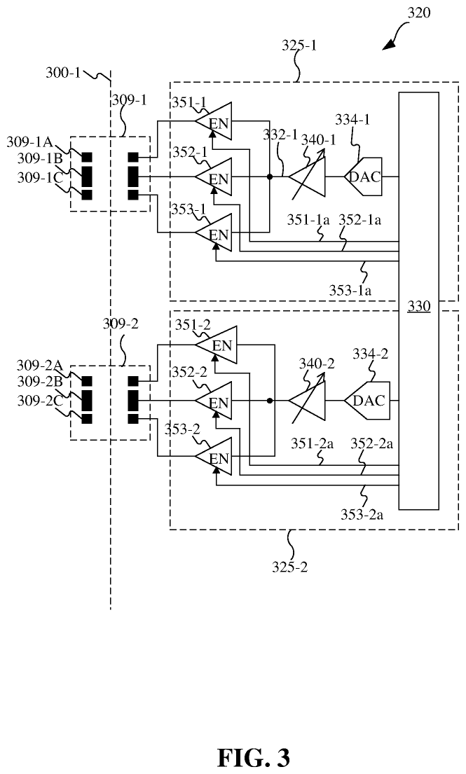

Reference is now made to FIG. 3, which illustrates an exemplary configuration of deflection control unit 320 associated with segmented charged-particle beam deflectors (e.g., primary electron beam deflectors 309-1 and 309-2), consistent with embodiments of the present disclosure. In some embodiments, each deflector may include a plurality of segments. Each of the plurality of segments may comprise a multi-pole structure including a plurality of electrodes configured to deflect the primary electron beam. Each segment may be electronically driven using a dedicated driver system or driver circuitry capable of supporting the scan frequency and driver linearity to adequately deflect the beam to form a large FOV.

As illustrated, each primary electron beam deflector may be electronically driven by a corresponding driver system. As an example, deflection control unit 320 may comprise a driver system 325-1 associated with primary electron beam deflector 309-1, and a driver system 325-2 associated with primary electron beam deflector 309-2. Driver system 325-1 may comprise a scan control unit 330, a DAC 334-1, a variable gain amplifier 340-1, and distributed output stages 351-1, 352-1, and 353-1. It is to be appreciated that although not illustrated, driver system 325-1 may include other components and circuitry such as power supplies, timing circuits, etc. as appropriately needed to manipulate primary electron beam traveling along primary optical axis 300-1. In some embodiments, each electrode of a deflector may include its own, corresponding DAC (e.g., a deflector with eight electrodes may include eight DACs).

Scan control unit 330 may be configured to generate and supply control signals 351-1a, 352-1a, and 353-1a, configured to activate an enable or a disable state of the corresponding distributed output stage. Scan control unit 330 may be further configured to generate a deflection signal 332-1 configured to be applied to one or more segments 309-1A, 309-1B, and 309-1C of primary electron beam deflector 309-1. In some embodiments, deflection control unit 320 may comprise a single scan control unit 330 configured to generate and supply control signals and deflection signals for multiple driver systems (e.g., 325-1 and 325-2). Deflection signal 332-1 may comprise a voltage signal applied to one or more segments of a primary electron beam deflector.

In some embodiments, driver system 325-1 may comprise circuitry such as DAC 334-1, configured to convert digital deflection signal 332-1 to an analog deflection signal. Driver system 325-1 may further comprise circuitry such as variable gain amplifier 340-1, configured to receive the analog deflection signal and generate a tunable amplitude of the deflection signal. In general, variable gain amplifiers (“VGAs”) are signal-conditioning amplifiers with electronically settable voltage gain. VGA 340-1 may comprise an analog VGA, or a digital VGA, or any suitable circuitry. In some embodiments, driver system 325-1 may further comprise circuitry such as distributed output stages, implemented as a plurality of direct-coupled amplifiers, or relays, or other suitable circuitry.

In an exemplary configuration of deflection control unit 320 such as illustrated in FIG. 3, segments 309-1A, 309-1B, and 309-1C of primary electron beam deflector 309-1 may be connected to distributed output stages 351-1, 352-1, and 353-1, respectively. The enable or disable status of distributed output stages 351-1, 352-1, and 353-1 may be activated by control signals 351-1a, 352-1a, and 353-1a, respectively, supplied by scan control unit 330. Variable gain amplifier 340-1 may be configured to output a tunable amplitude of deflection signal 332-1 applied to primary electron beam deflector 309-1 while maintaining low noise levels. In enable mode, activated by a control signal supplied by scan control unit 330, a distributed output stage (e.g., 351-1, 352-1, or 353-1) may reproduce the output signal from variable gain amplifier 340-1 to drive a corresponding segment of primary electron beam deflector 309-1. As an example, control signal 351-1a may activate an enable status of distributed output stage 351-1 such that distributed output stage 351-1 may reproduce the adjusted output signal comprising tunable amplitude of deflection signal 332-1 from variable gain amplifier 340-1 to be applied to segment 309-1A of primary electron beam deflector 309-1. The primary electron beam may be deflected based on the deflection signal applied to segment 309-1A of primary electron beam deflector 309-1. In some embodiments, in disable mode of a distributed output stage (e.g., 351-1, 352-1, or 353-1), the output signal may be grounded, and the distributed output stage may be powered down. Such a configuration may help reduce power consumption, among other advantages. Driver system 325-2 may be substantially similar to and may perform substantially similar functions as driver system 325-1 to control primary electron beam deflector 309-2. It is to be appreciated that disclosed embodiments may include two or more primary electron beam deflectors and corresponding driver systems.

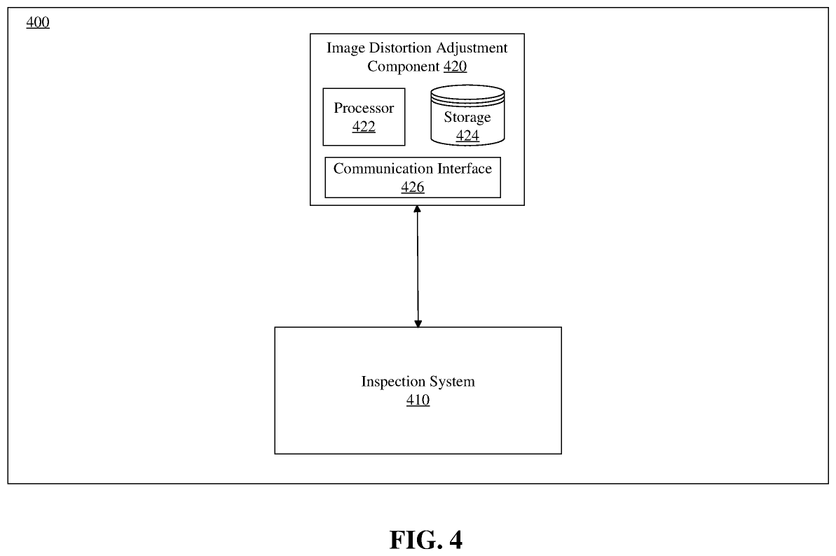

FIG. 4 is a schematic diagram of a system for adjusting distortion in images, consistent with embodiments of the present disclosure. System 400 may include an inspection system 410 and an image distortion adjustment component 420. Inspection system 410 and image distortion adjustment component 420 may be electrically coupled (directly or indirectly) to each other, either physically (e.g., by a cable) or remotely. Inspection system 410 may be the system described with respect to FIGS. 1, 2, and 3 used to acquire images of a wafer (see, e.g., sample 208 of FIG. 2). In some embodiments, components of system 400 may be implemented as one or more servers (e.g., where each server includes its own one or more processors). In some embodiments, components of system 400 may be implemented as software that may pull data from one or more databases of system 400. In some embodiments, system 400 may include one server or a plurality of servers. In some embodiments, system 400 may include one or more modules that are implemented by a controller (e.g., controller 109 of FIG. 1, controller 109 of FIG. 2).

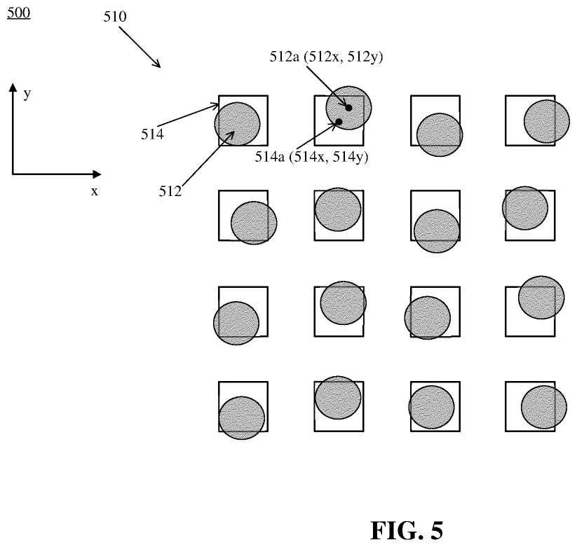

Inspection system 410 may obtain a plurality of images (e.g., image 510 of FIG. 5) of an area of a sample (e.g., sample 208 of FIG. 2). Each obtained image of the plurality of images may include features (e.g., contact holes, a metal line, a gate, etc.) of the sample. Inspection system 410 may transmit data including the plurality of images of the area of the sample to image distortion adjustment component 420.

Image distortion adjustment component 420 may include one or more processors (e.g., represented as processor 422, which can have one or more corresponding accelerators) and a storage 424. Image distortion adjustment component 420 may also include a communication interface 426 to receive from and send data to inspection system 410.

In some embodiments, processor 422 may be configured to extract a corresponding machine setting or parameters (e.g., deflectors, signal frequency of DACs, beam current, landing energy, pixel size, field of view size, etc.) associated with the plurality of images obtained by inspection system 410. In some embodiments, processor 422 may be configured to determine a plurality of position coordinates (e.g., x and y coordinates, position coordinate 514a of FIG. 5, etc.) where each position coordinate of the plurality of position coordinates corresponds to a feature (e.g., feature 512 of FIG. 5) of a plurality of features on the obtained images.

In some embodiments, processor 422 may be configured to obtain layout data (e.g., layout data 514 of FIG. 5) that corresponds to the obtained images. In some embodiments, the layout data may be obtained by querying a database of layout data. For example, a resist pattern design may be stored in a layout file for a wafer design. The layout file can be in a Graphic Database System (GDS) format, Graphic Database System II (GDS II) format, an Open Artwork System Interchange Standard (OASIS) format, a Caltech Intermediate Format (CIF), etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design. In some embodiments, a resist pattern design may correspond to a field of view (FOV) of inspection system 410 (e.g., a FOV of inspection system 410 may include one or more layout structures of a resist pattern design). That is, layout data may include intended positions (e.g., x and y coordinates, position coordinate 514a of FIG. 5, etc.) of features of a sample.

In some embodiments, processor 422 may be configured to use the extracted machine setting (e.g., parameters) and layout data to align the layout data of the features to the corresponding features in the obtained images.

In some embodiments, processor 422 may be configured to determine position (e.g., alignment) differences between the features in the obtained images and the corresponding features in the layout data and model the differences. For example, the differences may include a difference between a position coordinate (e.g., x and y coordinates) of a feature in an obtained image and the intended (e.g., target) position coordinate of the feature according to the layout data.

In some embodiments, processor 422 may be configured to determine a fingerprint of the position differences between the features in the obtained images and the corresponding features in the layout data. That is, processor 422 may determine a fingerprint of a plurality of alignment differences. In some embodiments, determining the fingerprint may include determining a rotational angle of the plurality of alignment differences. In some embodiments, processor 422 may be configured to determine the rotational angle of the alignment differences by any one of extracting a corresponding machine setting, performing an image analysis of the plurality of images, or fitting a model (e.g., a model different from the model used to model the differences between the features in the obtained images and the corresponding features in the layout data). In some embodiments, determining the rotational angle by extracting a corresponding machine setting may include extracting a voltage setting, extracting a DAC conversion factor, or any combination thereof to determine the rotational angle. In some embodiments, performing an image analysis of the plurality of images may include deriving the rotational angle from raw images. In some embodiments, determining the rotational angle by fitting a model may include using a set of rotational angles, fitting a model, and calculating the differences (e.g., residuals); changing the rotational angle; and searching for the rotational angles that result in the lowest residuals. In some embodiments, determining the rotational angle by fitting a model may include expanding the cost function to include the rotational angle as a free fitting variable and minimizing the cost function.

In some embodiments, the rotational angle may be zero (i.e., substantially zero rotational displacement of the fingerprint).

In some embodiments, processor 422 may be configured to use a model based on a corresponding machine setting. For example, the corresponding machine setting may include a plurality of deflector signal frequencies in a range corresponding to higher order distortion (e.g., distortion that is characterized by a polynomial expression order greater than three).

In some embodiments, higher order distortions may be modeled using an expression (e.g., a mathematical model) that may describe distortion from DACs, such as an expression appropriate to correct for distortions using greater than third order polynomial power terms and consistent with physical processes causing higher order distortions. Exemplary expressions for modeling linear displacements (e.g., displacements in the x and y directions) of features may include the following expression (1):

$$F ( x , y ) = {\sum }_{i , j} {f}_{i , j} ( x , y ) \qquad ( 1 )$$

where i is an iteration corresponding to a machine setting (e.g., i=1 for a first DAC signal frequency in a range of frequencies corresponding to higher order distortion), j denotes the number of functions required to capture the higher order distortion corresponding to this machine setting, f is a mathematical function which can be represented as a power series (e.g., an infinite power series) where the power is greater than 3, x is the x component of a position coordinate of a feature in an x-y coordinate system, and y is the y component of a position coordinate of the feature in the x-y coordinate system.

In some embodiments, two models may be used to model the linear differences. For example, a first model may correspond to a displacement in a first direction (e.g., in the x direction) and a second model may correspond to a displacement in a second direction (e.g., in the y direction). It should be understood that expression (1) above is exemplary and that other expressions may be used to model differences in the disclosed embodiments.

In some embodiments, model coefficients (e.g., part of the mathematical function f_{i,j}) may be determined through fitting expression (1) based on the differences data for a range of machine settings. In some embodiments, the machine setting may be a DAC signal frequency. In some embodiments, the lower bound of the DAC signal frequency may be determined by determining the frequency corresponding to the number of pixels in the FOV. In some embodiments, the upper bound of the DAC signal frequency may be determined by determining the frequency corresponding to the number of pixels in the FOV divided by a number of periods determined through electrical measurements of the DAC. In some embodiments, the frequency range may be determined based on the dependence of the 3σ of the residuals of displacement errors on the number of frequencies used in the model.

In some embodiments, the output of the model (e.g., the sum as shown in expression (1)) may be a net linear displacement of any point in the obtained images. For example, the output of the model may be a value corresponding to the distortion of the obtained images or a value by which the obtained images need to be corrected for distortion (e.g., how much a pixel of the obtained image needs to be adjusted in the x direction and y direction to correct for distortion).

In some embodiments, exemplary expressions for modeling rotational displacements (e.g., displacements in an angular direction) of a fingerprint of the linear displacements (e.g., the alignment differences) may include the following expression (2):

$$F ( φ , x , y ) = {\sum }_{i} {f}_{i} ( φ , x , y ) \qquad ( 2 )$$

where i is an iteration corresponding to a machine setting (e.g., i=1 for a first DAC signal frequency in a range of frequencies corresponding to higher order distortion), f is a mathematical function which can be represented as any series (e.g., any infinite power series, an infinite power series where the power is greater than 3, Fourier series, Taylor series, trigonometric series, power series, geometric series, etc.), φ is a rotational angle of a fingerprint of the linear displacements, x is the x component of a vector of the rotational angle of the fingerprint in an x-y coordinate system, and y is the y component of a vector of the rotational angle of the fingerprint in the x-y coordinate system.

It should be understood that expression (2) above is exemplary and that other expressions may be used to model fingerprint differences in the disclosed embodiments.

In some embodiments, model coefficients (e.g., part of the mathematical function fᵢ) may be determined through fitting expression (2) based on the differences data for a range of machine settings. In some embodiments, the machine setting may be a DAC signal frequency. In some embodiments, the lower bound of the DAC signal frequency may be determined by determining the frequency corresponding to the number of pixels in the FOV. In some embodiments, the upper bound of the DAC signal frequency may be determined by determining the frequency corresponding to the number of pixels in the FOV divided by a number of periods determined through electrical measurements of the DAC. In some embodiments, the frequency range may be determined based on the dependence of the 3σ of the residuals of displacement errors on the number of frequencies used in the model.

In some embodiments, the output of the model (e.g., the sum as shown in expression (2)) may be a net rotational displacement of the fingerprint of the alignment differences in the obtained images. For example, the output of the model may be a value corresponding to the distortion of the fingerprint or a value by which the fingerprint needs to be corrected for distortion.

In some embodiments, processor 422 may be configured to determine at least one metrology error associated with the position (e.g., alignment) differences determined above. For example, processor 422 may use the output of the models (e.g., associated with expression (1) or expressions (1) and (2)) to determine metrology errors and to determine which machine settings (e.g., parameters, hardware correctable parameters, etc.) may be changed to correct for the metrology errors. For example, processor 422 may determine at least one new machine setting or parameter (e.g., different machine setting or parameter) and repeat one or more steps described above using the at least one new machine setting (e.g., different parameter values) so that the models output different values and correct for the at least one metrology error. In some embodiments, some metrology errors (e.g., errors that are not hardware correctable) may be determined and corrected for by software modifications.

In some embodiments, processor 422 may be configured to adjust or correct at least one position coordinate corresponding to a feature using the modeling. For example, processor 422 may be configured to use the modeling to adjust or correct a pixel of the image such that the adjustment is a distortion correction of the image.

In some embodiments, processor 422 may be configured to extract at least one measurement (e.g., width of a line, roughness of a line, diameter of a contact hole, shape of a contact hole, etc.) from the adjusted or corrected image. For example, processor 422 may be configured to extract measurements from the adjusted image for inspection of a sample.

Reference is now made to FIG. 5, a schematic diagram 500 illustrating an exemplary alignment of an image 510 of an area of a sample (e.g., sample 208 of FIG. 2) with corresponding layout data, consistent with embodiments of the present disclosure.

As described above, an inspection system (e.g., inspection system 410 of FIG. 4) may obtain a plurality of images of an area of a sample. For example, image 510 of the alignment may include features 512 (e.g., contact holes, a metal line, a gate, etc.) of the sample. In some embodiments, each feature 512 may include a corresponding position coordinate 512a (depicted as point in the center of feature 512) with an x-axis coordinate 512x and a y-axis coordinate 512y.

In some embodiments, layout data 514 corresponding to features 512 of image 510 of the alignment may include an intended (e.g., targeted) position coordinate 514a (depicted as point in the center of layout data 514) with an x-axis coordinate 514x and a y-axis coordinate 514y. That is, layout data 514 may include intended positions of features 512 of the sample. It should be understood that layout data 514 may not be depicted in image 510 in practice, but is shown here for illustrative purposes.

In some embodiments, a processor (e.g., processor 422 of FIG. 4) may be configured to determine position (e.g., alignment) differences between features 512 and the corresponding features in layout data 514 and model the differences. For example, the differences may include a difference between position coordinate 512a of feature 512 and intended position coordinate 514a of feature 512 according to layout data 514.

In some embodiments, the processor may be configured to use a model based on the corresponding machine setting. In some embodiments, two models may be used to model the differences. For example, a first model may correspond to a displacement between feature 512 and layout data 514 in a first direction (e.g., in the x direction) and a second model may correspond to a displacement between feature 512 and layout data 514 in a second direction (e.g., in the y direction).

In some embodiments, the output of the model (e.g., the sum as shown in expression (1) above) may be a net displacement of any point in the obtained images. For example, the output of the model may be a value corresponding to the distortion of feature 512 in image 510 or a value by which image 510 need to be corrected for distortion (e.g., how much a pixel of feature 512 in image 510 needs to be adjusted in the x direction and y direction to correct for distortion).

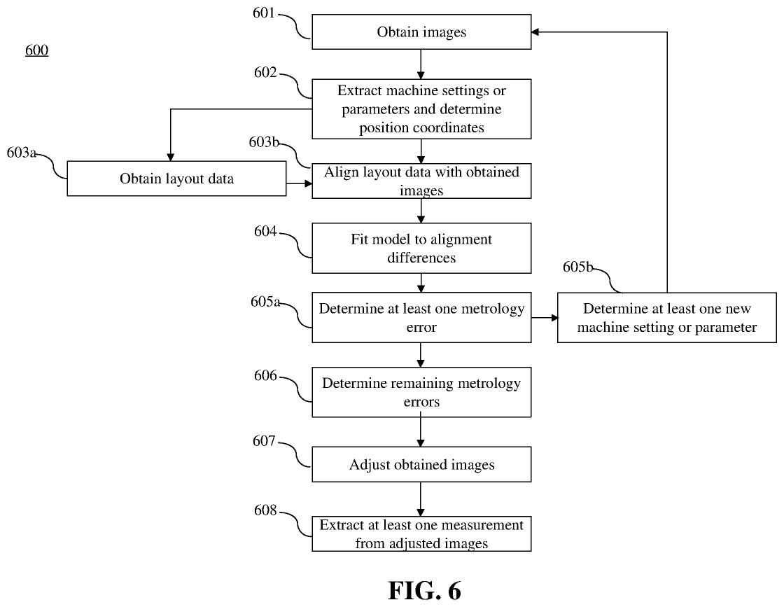

Reference is now made to FIG. 6, a flowchart illustrating an exemplary process 600 of adjusting distortion in images, consistent with embodiments of the present disclosure. The steps of method 600 can be performed by a system (e.g., system 400 of FIG. 4) executing on or otherwise using the features of a computing device (e.g., controller 109 of FIG. 1) for purposes of illustration. It is appreciated that the illustrated method 600 can be altered to modify the order of steps and to include additional steps.

At step 601, an inspection system (e.g., inspection system 410 of FIG. 4) may obtain a plurality of images (e.g., image 510 of FIG. 5) of an area of a sample (e.g., sample 208 of FIG. 2). Each obtained image of the plurality of images may include features (e.g., contact holes, a metal line, a gate, etc.) of the sample. The inspection system may transmit data including the plurality of images of the area of the sample to an image distortion adjustment component (e.g., image distortion adjustment component 420 of FIG. 4).

At step 602, a processor (e.g., processor 422 of FIG. 4) may be configured to extract a corresponding machine setting or parameters (e.g., deflectors, signal frequency of DACs, beam current, landing energy, pixel size, field of view size, etc.) associated with the plurality of images obtained by the inspection system. In some embodiments, the processor may be configured to determine a plurality of position coordinates (e.g., x and y coordinates, position coordinate 514a of FIG. 5, etc.) where each position coordinate of the plurality of position coordinates corresponds to a feature (e.g., feature 512 of FIG. 5) of a plurality of features on the obtained images.

At step 603a, the processor may be configured to obtain layout data (e.g., layout data 514 of FIG. 5) that corresponds to the obtained images. In some embodiments, the layout data may be obtained by querying a database of layout data. For example, a resist pattern design may be stored in a layout file for a wafer design. The layout file can be in a Graphic Database System (GDS) format, Graphic Database System II (GDS II) format, an Open Artwork System Interchange Standard (OASIS) format, a Caltech Intermediate Format (CIF), etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design. In some embodiments, a resist pattern design may correspond to a field of view (FOV) of inspection system 410 (e.g., a FOV of inspection system 410 may include one or more layout structures of a resist pattern design). That is, layout data may include intended positions (e.g., x and y coordinates, position coordinate 514a of FIG. 5, etc.) of features of a sample.

At step 603b, the processor may be configured to use the extracted machine setting (e.g., parameters) and layout data to align the layout data of the features to the corresponding features in the obtained images. In some embodiments, the processor may be configured to proceed from step 602 to step 603b directly (instead of from step 602 to step 603a to step 603b). For example, the processor may be configured to proceed from step 602 to step 603b when the layout data is the same for multiple iterations of obtaining images.

A step 604, the processor may be configured to determine position (e.g., alignment) differences between the features in the obtained images and the corresponding features in the layout data and model the differences. For example, the differences may include a difference between a position coordinate (e.g., x and y coordinates) of a feature in an obtained image and the intended (e.g., target) position coordinate of the feature according to the layout data.

In some embodiments, the processor may be configured to use a model based on the corresponding machine setting. For example, the corresponding machine setting may include a plurality of deflector signal frequencies in a range corresponding to higher order distortion (e.g., distortion that is characterized by a polynomial expression order greater than three).

In some embodiments, higher order distortions may be modeled using an expression (e.g., a mathematical model) that may describe distortion from DACs, such as an expression appropriate to correct for distortions using greater than third order polynomial power terms and consistent with physical processes causing higher order distortions. Exemplary expressions may include expression (1):

$$F ( x , y ) = {\sum }_{i , j} {f}_{i , j} ( x , y ) \qquad ( 1 )$$

where i is an iteration corresponding to a machine setting (e.g., i=1 for a first DAC signal frequency in a range of frequencies corresponding to higher order distortion), j denotes the number of functions required to capture the higher order distortion corresponding to this machine setting, f is a mathematical function which can be represented as a power series (e.g., an infinite power series) where the power is greater than 3, x is the x component of a position coordinate of a feature in an x-y coordinate system, and y is the y component of a position coordinate of the feature in the x-y coordinate system.

In some embodiments, two models may be used to model the differences. For example, a first model may correspond to a displacement in a first direction (e.g., in the x direction) and a second model may correspond to a displacement in a second direction (e.g., in the y direction). It should be understood that expression (1) above is exemplary and that other expressions may be used to model differences in the disclosed embodiments.

In some embodiments, model coefficients (e.g., part of the mathematical function f_{i,j}) may be determined through fitting expression (1) based on the differences data for a range of machine settings. In some embodiments, the machine setting may be a DAC signal frequency. In some embodiments, the lower bound of the DAC signal frequency may be determined by determining the frequency corresponding to the number of pixels in the FOV. In some embodiments, the upper bound of the DAC signal frequency may be determined by determining the frequency corresponding to the number of pixels in the FOV divided by a number of periods determined through electrical measurements of the DAC. In some embodiments, the frequency range may be determined based on the dependence of the 3σ of the residuals of displacement errors on the number of frequencies used in the model.

In some embodiments, the output of the model (e.g., the sum as shown in expression (1)) may be a net displacement of any point in the obtained images. For example, the output of the model may be a value corresponding to the distortion of the obtained images or a value by which the obtained images need to be corrected for distortion (e.g., how much a pixel of the obtained image needs to be adjusted in the x direction and y direction to correct for distortion).

At step 605a, the processor may be configured to determine at least one metrology error associated with the position (e.g., alignment) differences determined above. For example, the processor may use the output of the model to determine metrology errors and to determine which machine settings (e.g., parameters, hardware correctable parameters, etc.) may be changed to correct for the metrology errors. For example, at step 605b, the processor may be configured to determine at least one new machine setting or parameter (e.g., different machine setting or parameter), and steps 601-604 may be repeated using the at least one new machine setting (e.g., different parameter values) so that the model outputs different values and corrects for the at least one metrology error.

For example, the images obtained may be a first plurality of images obtained at a first machine setting and the alignment differences may be first alignment differences between a plurality of features on the first plurality of images and corresponding features in layout data corresponding to the first plurality of images. The modeling may be a first modeling of the first alignment differences. In some embodiments, the processor may adjust at least one feature of the plurality of features on at least one image of the first plurality of images using the first modeling (e.g., step 607 below). In some embodiments, the processor may determine at least one metrology error associated with the first alignment differences and determine a second machine setting based on the at least one metrology error. The processor may obtain a second plurality of images at the second machine setting, determine second alignment differences between a plurality of features on the second plurality of images and corresponding features in layout data corresponding to the second plurality of images, and model the second alignment differences using a second modeling. In some embodiments, the processor may adjust at least one feature of the plurality of features on at least one image of the second plurality of images using the second modeling.

At step 606, some metrology errors (e.g., errors that are not hardware correctable, errors besides the errors determined in step 605a, etc.) may be determined and corrected for by software modifications.

At step 607, the processor may be configured to adjust or correct at least one position coordinate corresponding to a feature using the modeling. For example, the processor may be configured to use the modeling to adjust or correct a pixel of the image such that the adjustment is a distortion correction of the image.

At step 608, the processor may be configured to extract at least one measurement (e.g., width of a line, roughness of a line, diameter of a contact hole, shape of a contact hole, etc.) from the adjusted or corrected image. For example, the processor may be configured to extract measurements from the adjusted image for inspection of a sample.

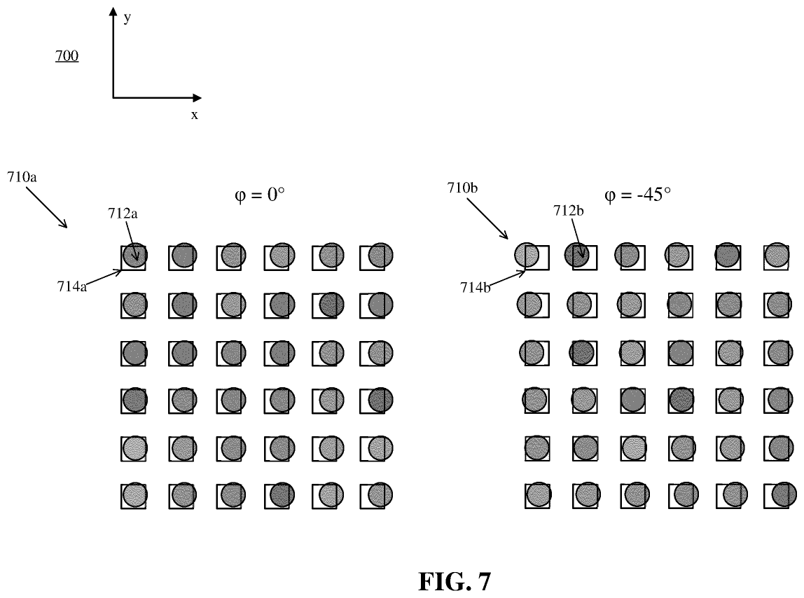

Reference is now made to FIG. 7, a schematic diagram 700 illustrating an exemplary image 710a of an area of a sample (e.g., sample 208 of FIG. 2) with corresponding layout data and an image 710b of an area of a sample (e.g., sample 208 of FIG. 2) with corresponding layout data, consistent with embodiments of the present disclosure.

As described above, an inspection system (e.g., inspection system 410 of FIG. 4) may obtain a plurality of images of an area of a sample. For example, image 710a of the alignment may include features 712a (e.g., contact holes, a metal line, a gate, features 512 of FIG. 5, etc.) of the sample. In some embodiments, each feature 712a may include a corresponding position coordinate (e.g., position coordinate 512a of FIG. 5) with an x-axis coordinate (e.g., x-axis coordinate 512x of FIG. 5) and a y-axis coordinate (e.g., y-axis coordinate 512y of FIG. 5). In some embodiments, a processor may generate a fingerprint of the alignment differences (e.g., a model of the alignment differences) between features 712a and layout data 714a (e.g., layout data 514 of FIG. 5). It should be understood that layout data 714a may not be depicted in image 710a in practice, but is shown here for illustrative purposes.

In some embodiments, the fingerprint or fingerprints of features 712a may include a corresponding rotational angle φ between the fingerprint and a reference fingerprint. In some embodiments, the rotational angle φ of a fingerprint may be zero (i.e., substantially zero rotational displacement of the fingerprint). For example, the fingerprint or fingerprints of features 712a may have a rotational angle φ of zero.

In some embodiments, similar to image 710a, image 710b of an alignment may include features 712b (e.g., contact holes, a metal line, a gate, features 512 of FIG. 5, etc.) of a sample. In some embodiments, each feature 712b may include a corresponding position coordinate (e.g., position coordinate 512a of FIG. 5) with an x-axis coordinate (e.g., x-axis coordinate 512x of FIG. 5) and a y-axis coordinate (e.g., y-axis coordinate 512y of FIG. 5). In some embodiments, a processor may generate a fingerprint of the alignment differences (e.g., a model of the alignment differences) between features 712b and layout data 714b (e.g., layout data 514 of FIG. 5). It should be understood that layout data 714b may not be depicted in image 710b in practice, but is shown here for illustrative purposes.

In some embodiments, the fingerprint or fingerprints of features 712b may include a corresponding rotational angle φ between the fingerprint and a reference fingerprint. In some embodiments, the rotational angle φ of a fingerprint may be non-zero (i.e., a rotational angle φ of −45° may correspond to a rotational displacement of −45° of the fingerprint). For example, the fingerprint or fingerprints of features 712b may have a rotational angle φ of −45°. That is, a model of the alignment differences of features 712b may have a rotation angle φ of −45°, while the actual displacement of features 712b in image 710b may be in the x or y directions.

In some embodiments, the fingerprint of features 712b of image 710b of the alignment may include an intended (e.g., targeted) orientation.

In some embodiments, a processor (e.g., processor 422 of FIG. 4) may be configured to model the linear alignment differences, described above, by determining a rotational (e.g., rotational alignment) difference between the fingerprint and a reference fingerprint and model the difference. For example, the difference may include a difference in rotational angle φ between the fingerprint and the intended orientation of the fingerprint according to the reference fingerprint.

In some embodiments, the processor may be configured to use a model based on a corresponding machine setting.

In some embodiments, the output of the model (e.g., the sum as shown in expression (2) above) may be a net rotational displacement of the fingerprint of the alignment differences. For example, the output of the model may be a value corresponding to the distortion of fingerprint 712b.

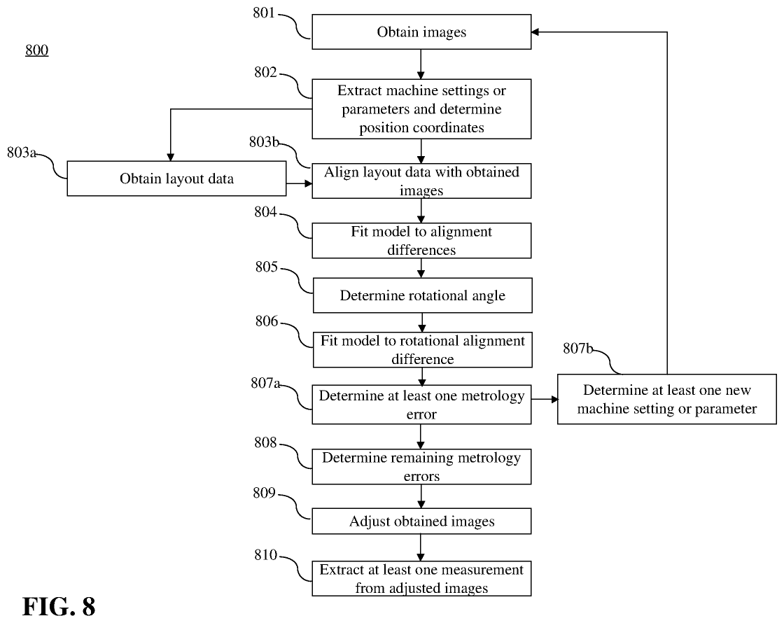

Reference is now made to FIG. 8, a flowchart illustrating an exemplary process 800 of adjusting distortion in images, consistent with embodiments of the present disclosure. The steps of method 800 can be performed by a system (e.g., system 400 of FIG. 4) executing on or otherwise using the features of a computing device (e.g., controller 109 of FIG. 1) for purposes of illustration. It is appreciated that the illustrated method 800 can be altered to modify the order of steps and to include additional steps.

At step 801, an inspection system (e.g., inspection system 410 of FIG. 4) may obtain a plurality of images (e.g., image 510 of FIG. 5) of an area of a sample (e.g., sample 208 of FIG. 2). Each obtained image of the plurality of images may include features (e.g., contact holes, a metal line, a gate, etc.) of the sample. The inspection system may transmit data including the plurality of images of the area of the sample to an image distortion adjustment component (e.g., image distortion adjustment component 420 of FIG. 4).

At step 802, a processor (e.g., processor 422 of FIG. 4) may be configured to extract a corresponding machine setting or parameters (e.g., deflectors, signal frequency of DACs, beam current, landing energy, pixel size, field of view size, etc.) associated with the plurality of images obtained by the inspection system. In some embodiments, the processor may be configured to determine a plurality of position coordinates (e.g., x and y coordinates, position coordinate 514a of FIG. 5, etc.) where each position coordinate of the plurality of position coordinates corresponds to a feature (e.g., feature 512 of FIG. 5) of a plurality of features on the obtained images.

At step 803a, the processor may be configured to obtain layout data (e.g., layout data 514 of FIG. 5) that corresponds to the obtained images. In some embodiments, the layout data may be obtained by querying a database of layout data. For example, a resist pattern design may be stored in a layout file for a wafer design. The layout file can be in a Graphic Database System (GDS) format, Graphic Database System II (GDS II) format, an Open Artwork System Interchange Standard (OASIS) format, a Caltech Intermediate Format (CIF), etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design. In some embodiments, a resist pattern design may correspond to a field of view (FOV) of inspection system 410 (e.g., a FOV of inspection system 410 may include one or more layout structures of a resist pattern design). That is, layout data may include intended positions (e.g., x and y coordinates, position coordinate 514a of FIG. 5, etc.) of features of a sample.

At step 803b, the processor may be configured to use the extracted machine setting (e.g., parameters) and layout data to align the layout data of the features to the corresponding features in the obtained images. In some embodiments, the processor may be configured to proceed from step 802 to step 803b directly (instead of from step 802 to step 803a to step 803b). For example, the processor may be configured to proceed from step 802 to step 803b when the layout data is the same for multiple iterations of obtaining images.

At step 804, the processor may be configured to determine position (e.g., alignment) differences between the features in the obtained images and the corresponding features in the layout data and model the differences. For example, the differences may include a difference between a position coordinate (e.g., x and y coordinates) of a feature in an obtained image and the intended (e.g., target) position coordinate of the feature according to the layout data.

In some embodiments, the processor may be configured to use a model based on the corresponding machine setting. For example, the corresponding machine setting may include a plurality of deflector signal frequencies in a range corresponding to higher order distortion (e.g., distortion that is characterized by a polynomial expression order greater than three).

In some embodiments, higher order distortions may be modeled using an expression (e.g., a mathematical model) that may describe distortion from DACs, such as an expression appropriate to correct for distortions using greater than third order polynomial power terms and consistent with physical processes causing higher order distortions. Exemplary expressions may include expression (1):

$$F ( x , y ) = {\sum }_{i , j} {f}_{i , j} ( x , y ) \qquad ( 1 )$$

where i is an iteration corresponding to a machine setting (e.g., i=1 for a first DAC signal frequency in a range of frequencies corresponding to higher order distortion), j denotes the number of functions required to capture the higher order distortion corresponding to this machine setting, f is a mathematical function which can be represented as any series (e.g., any infinite power series, an infinite power series where the power is greater than 3, Fourier series, Taylor series, trigonometric series, power series, geometric series, etc.), x is the x component of a position coordinate of a feature in an x-y coordinate system, and y is the y component of a position coordinate of the feature in the x-y coordinate system.

In some embodiments, two models may be used to model the differences. For example, a first model may correspond to a displacement in a first direction (e.g., in the x direction) and a second model may correspond to a displacement in a second direction (e.g., in the y direction). It should be understood that expression (1) above is exemplary and that other expressions may be used to model differences in the disclosed embodiments.

In some embodiments, model coefficients (e.g., part of the mathematical function f_{i,j}) may be determined through fitting expression (1) based on the differences data for a range of machine settings. In some embodiments, the machine setting may be a DAC signal frequency. In some embodiments, the lower bound of the DAC signal frequency may be determined by determining the frequency corresponding to the number of pixels in the FOV. In some embodiments, the upper bound of the DAC signal frequency may be determined by determining the frequency corresponding to the number of pixels in the FOV divided by a number of periods determined through electrical measurements of the DAC. In some embodiments, the frequency range may be determined based on the dependence of the 3σ of the residuals of displacement errors on the number of frequencies used in the model.

In some embodiments, the output of the model (e.g., the sum as shown in expression (1)) may be a net displacement of any point in the obtained images. For example, the output of the model may be a value corresponding to the distortion of the obtained images or a value by which the obtained images need to be corrected for distortion (e.g., how much a pixel of the obtained image needs to be adjusted in the x direction and y direction to correct for distortion).

At step 805, the processor may be configured to determine a rotational angle difference (e.g., rotational angle 712φ of FIG. 7) between a fingerprint of the linear displacements (e.g., alignment differences) and the reference fingerprint. In some embodiments, the rotational angle may be zero (i.e., substantially zero rotational displacement of the fingerprint).

For example, the difference may include a difference in rotational angle between a fingerprint having an orientation and the intended (e.g., target) orientation of the fingerprint according to the reference fingerprint. In some embodiments, the processor may be configured to determine rotational alignment differences (e.g., a rotational angle between a fingerprint of the alignment differences and the reference fingerprint) by any one of extracting a corresponding machine setting, performing an image analysis of the plurality of images, or fitting a model (e.g., a model different from the model used to model the differences between the features in the obtained images and the corresponding features in the layout data). In some embodiments, determining the rotational angle by extracting a corresponding machine setting may include extracting a voltage setting, extracting a DAC conversion factor, or any combination thereof to determine the rotational angle. In some embodiments, performing an image analysis of the plurality of images may include deriving the rotational angle from raw images. In some embodiments, determining the rotational angle by fitting a model may include using a set of rotational angles, fitting a model, and calculating the differences (e.g., residuals); changing the rotational angle; and searching for the rotational angles that result in the lowest residuals. In some embodiments, determining the rotational angle by fitting a model may include expanding the cost function to include the rotational angle as a free fitting variable and minimizing the cost function.

At step 806, the processor may be configured to model the rotational displacement (e.g., displacement of the alignment differences).

In some embodiments, the processor may be configured to use a model based on the corresponding machine setting. For example, the corresponding machine setting may include a plurality of deflector signal frequencies in a range corresponding to higher order distortion (e.g., distortion that is characterized by a polynomial expression order greater than three).

In some embodiments, higher order distortions may be modeled using an expression (e.g., a mathematical model) that may describe distortion from DACs, such as an expression appropriate to correct for distortions using greater than third order polynomial power terms and consistent with physical processes causing higher order distortions. Exemplary expressions may include expression (2):

$$F ( φ , x , y ) = {\sum }_{i} {f}_{i} ( φ , x , y ) \qquad ( 2 )$$

where i is an iteration corresponding to a machine setting (e.g., i=1 for a first DAC signal frequency in a range of frequencies corresponding to higher order distortion), f is a mathematical function which can be represented as a power series (e.g., an infinite power series) where the power is greater than 3, φ is a rotational angle between a fingerprint of the alignment differences and the reference fingerprint, x is the x component of a vector of the rotational angle of the fingerprint in an x-y coordinate system, and y is the y component of a vector of the rotational angle of the fingerprint in the x-y coordinate system.

It should be understood that expression (2) above is exemplary and that other expressions may be used to model differences in the disclosed embodiments.

In some embodiments, model coefficients (e.g., part of the mathematical function fᵢ) may be determined through fitting expression (2) based on the differences data for a range of machine settings. In some embodiments, the machine setting may be a DAC signal frequency. In some embodiments, the lower bound of the DAC signal frequency may be determined by determining the frequency corresponding to the number of pixels in the FOV. In some embodiments, the upper bound of the DAC signal frequency may be determined by determining the frequency corresponding to the number of pixels in the FOV divided by a number of periods determined through electrical measurements of the DAC. In some embodiments, the frequency range may be determined based on the dependence of the 3σ of the residuals of displacement errors on the number of frequencies used in the model.

In some embodiments, the output of the model (e.g., the sum as shown in expression (2)) may be a net rotational displacement of the fingerprint of the alignment differences in the obtained images. For example, the output of the model may be a value corresponding to the distortion of the fingerprint or a value by which the fingerprint needs to be corrected for distortion.

At step 807a, the processor may be configured to determine at least one metrology error associated with the position (e.g., alignment) differences determined above. For example, the processor may use the output of the models (e.g., associated with expression (1) or expressions (1) and (2)) to determine metrology errors and to determine which machine settings (e.g., parameters, hardware correctable parameters, etc.) may be changed to correct for the metrology errors. For example, at step 807b, the processor may be configured to determine at least one new machine setting or parameter (e.g., different machine setting or parameter), and steps 801-806 may be repeated using the at least one new machine setting (e.g., different parameter values) so that the models output different values and correct for the at least one metrology error.

For example, the images obtained may be a first plurality of images obtained at a first machine setting and the alignment differences may be first alignment differences between a plurality of features on the first plurality of images and corresponding features in layout data corresponding to the first plurality of images. The modeling (e.g., associated with expression (1) or expression (2)) may be a first modeling of the first alignment differences. In some embodiments, the processor may adjust at least one feature of the plurality of features on at least one image of the first plurality of images using the first modeling (e.g., step 809 below). In some embodiments, the processor may determine at least one metrology error associated with the first alignment differences and determine a second machine setting based on the at least one metrology error. The processor may obtain a second plurality of images at the second machine setting, determine second alignment differences between a plurality of features on the second plurality of images and corresponding features in layout data corresponding to the second plurality of images, and model the second alignment differences using a second modeling. In some embodiments, the processor may adjust at least one feature of the plurality of features on at least one image of the second plurality of images using the second modeling.

At step 808, some metrology errors (e.g., errors that are not hardware correctable, errors besides the errors determined in step 807a, etc.) may be determined and corrected for by software modifications.

At step 809, the processor may be configured to adjust or correct at least one position coordinate corresponding to a feature using the modeling. For example, the processor may be configured to use the modeling to adjust or correct a pixel of the image such that the adjustment is a distortion correction of the image.

At step 810, the processor may be configured to extract at least one measurement (e.g., width of a line, roughness of a line, diameter of a contact hole, shape of a contact hole, etc.) from the adjusted or corrected image. For example, the processor may be configured to extract measurements from the adjusted image for inspection of a sample.

A non-transitory computer readable medium may be provided that stores instructions for a processor of a controller (e.g., controller 109 of FIG. 1) for controlling the electron beam tool or controlling processors (e.g., processor 422 of FIG. 4) of other systems and servers, consistent with embodiments in the present disclosure. These instructions may allow the one or more processors to carry out image processing, data processing, beamlet scanning, database management, graphical display, operations of a charged particle beam apparatus, or another imaging device, or the like. In some embodiments, the non-transitory computer readable medium may be provided that stores instructions for a processor to perform the steps of process 600. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:

1. A method for distortion adjustment, the system comprising:
obtaining a plurality of images;
determining alignment differences between a plurality of features on the plurality of images and corresponding features in layout data corresponding to the plurality of images;
modeling the alignment differences; and
adjusting at least one of:
a machine setting corresponding to obtaining the plurality of images; or
at least one feature of the plurality of features on at least one image of the plurality of images using the modeling.

2. The method of clause 1, wherein obtaining the plurality of images further comprises extracting the corresponding machine setting.

3. The method of any one of clauses 1-2, wherein determining the alignment differences comprises using the corresponding machine setting and the layout data to align the plurality of features on the plurality of images with the corresponding features in the layout data.

4. The method of any one of clauses 1-2, wherein modeling the alignment differences comprises using a model based on the corresponding machine setting.

5. The method of clause 4, wherein the corresponding machine setting comprises a plurality of deflector signal frequencies.

6. The method of clause 4, wherein the model characterizes higher order distortions.

7. The method of clause 4, wherein the model comprises a plurality of models, including at least one model corresponding to a first dimension of the alignment differences and at least one model corresponding to a second dimension of the alignment differences.

8. The method of any one of clauses 1-7, wherein the adjustment is a distortion correction.

9. The method of any one of clauses 1-8, further comprising determining a plurality of metrology errors associated with the alignment differences and tuning the modeling based on the plurality of metrology errors.

10. The method of any one of clauses 1-9, further comprising extracting a plurality of measurements from the adjusted at least one image.

11. The method of any one of clauses 1-10, further comprising determining a fingerprint of the alignment differences.

12. The method of clause 11, wherein determining the fingerprint of the alignment differences comprises determining a rotational angle of the alignment differences.

13. The method of clause 12, wherein determining the rotational angle of the alignment differences comprises any one of extracting a machine setting, an image analysis of the plurality of images, or fitting a model.

14. The method of any one of clauses 1-13, wherein modeling the alignment differences comprises a rotational adjustment of the fingerprint of the alignment differences.

15. A system for distortion adjustment, the system comprising:
a controller including circuitry configured to cause the system to perform:
obtaining a plurality of images;
determining alignment differences between a plurality of features on the plurality of images and corresponding features in layout data corresponding to the plurality of images;
modeling the alignment differences; and
adjusting at least one of:
a machine setting corresponding to obtaining the plurality of images; or
at least one feature of the plurality of features on at least one image of the plurality of images using the modeling.

16. The system of clause 15, wherein obtaining the plurality of images further comprises extracting the corresponding machine setting.

17. The system of any one of clauses 15-16, wherein determining the alignment differences comprises using the corresponding machine setting and the layout data to align the plurality of features on the plurality of images with the corresponding features in the layout data.

18. The system of any one of clauses 15-16, wherein modeling the alignment differences comprises using a model based on the corresponding machine setting.

19. The system of clause 18, wherein the corresponding machine setting comprises a plurality of deflector signal frequencies.

20. The system of clause 18, wherein the model characterizes higher order distortions.

21. The system of clause 18, wherein the model comprises a plurality of models, including at least one model corresponding to a first dimension of the alignment differences and at least one model corresponding to a second dimension of the alignment differences.

22. The system of any one of clauses 15-21, wherein the adjustment is a distortion correction.

23. The system of any one of clauses 15-22, wherein the circuitry is further configured to cause the system to perform determining a plurality of metrology errors associated with the alignment differences and tuning the modeling based on the plurality of metrology errors.

24. The system of any one of clauses 15-23, wherein the circuitry is further configured to cause the system to perform extracting a plurality of measurements from the adjusted at least one image.

25. The system of any one of clauses 15-24, wherein the controller including circuitry is further configured to cause the system to perform determining a fingerprint of the alignment differences.

26. The system of clause 25, wherein determining the fingerprint of the alignment differences comprises determining a rotational angle of the alignment differences.

27. The system of clause 26, wherein determining the rotational angle of the alignment differences comprises any one of extracting a machine setting, an image analysis of the plurality of images, or fitting a model.

28. The system of any one of clauses 15-27, wherein modeling the alignment differences comprises a rotational adjustment of the fingerprint of the alignment differences.

29. A non-transitory computer readable medium that stores a set of instructions that is executable by at least one processor of a computing device to cause the computing device to perform a method for distortion adjustment, the method comprising:
obtaining a plurality of images;
determining alignment differences between a plurality of features on the plurality of images and corresponding features in layout data corresponding to the plurality of images;
modeling the alignment differences; and
adjusting at least one of:
a machine setting corresponding to obtaining the plurality of images; or
at least one feature of the plurality of features on at least one image of the plurality of images using the modeling.

30. The non-transitory computer readable medium of clause 29, wherein obtaining the plurality of images further comprises extracting the corresponding machine setting.

31. The non-transitory computer readable medium of any one of clauses 29-30, wherein determining the alignment differences comprises using the corresponding machine setting and the layout data to align the plurality of features on the plurality of images with the corresponding features in the layout data.

32. The non-transitory computer readable medium of any one of clauses 29-30, wherein modeling the alignment differences comprises using a model based on the corresponding machine setting.

33. The non-transitory computer readable medium of clause 32, wherein the corresponding machine setting comprises a plurality of deflector signal frequencies.

34. The non-transitory computer readable medium of clause 32, wherein the model characterizes higher order distortions.

35. The non-transitory computer readable medium of clause 32, wherein the model comprises a plurality of models, including at least one model corresponding to a first dimension of the alignment differences and at least one model corresponding to a second dimension of the alignment differences.

36. The non-transitory computer readable medium of any one of clauses 29-35, wherein the adjustment is a distortion correction.

37. The non-transitory computer readable medium of any one of clauses 29-36, wherein the set of instructions that is executable by at least one processor of a computing device to cause the computing device to further perform determining a plurality of metrology errors associated with the alignment differences and tuning the modeling based on the plurality of metrology errors.

38. The non-transitory computer readable medium of any one of clauses 29-37, wherein the set of instructions that is executable by at least one processor of a computing device to cause the computing device to further perform extracting a plurality of measurements from the adjusted at least one image.

39. The non-transitory computer readable medium of any one of clauses 29-38, further comprising determining a fingerprint of the alignment differences.

40. The non-transitory computer readable medium of clause 39, wherein determining the fingerprint of the alignment differences comprises determining a rotational angle of the alignment differences.

41. The non-transitory computer readable medium of clause 40, wherein determining the rotational angle of the alignment differences comprises any one of extracting a corresponding machine setting, an image analysis of the plurality of images, or fitting a model.

42. The non-transitory computer readable medium of any one of clauses 29-41, wherein modeling the alignment differences comprises a rotational adjustment of the fingerprint of the alignment differences.

43. A method for distortion adjustment, the method comprising:
obtaining a first plurality of images at a first machine setting;
determining first alignment differences between a plurality of features on the first plurality of images and corresponding features in layout data corresponding to the first plurality of images;
modeling the first alignment differences using a first modeling;
determining at least one metrology error associated with the first alignment differences;
determining a second machine setting based on the at least one metrology error;
obtaining a second plurality of images at the second machine setting;
determining second alignment differences between a plurality of features on the second plurality of images and corresponding features in layout data corresponding to the second plurality of images;
modeling the second alignment differences using a second modeling; and
adjusting at least one of:
the second machine setting; or
at least one feature of the plurality of features on at least one image of the second plurality of images using the second modeling.

44. A system for distortion adjustment, the system comprising:
a controller including circuitry configured to cause the system to perform:
obtaining a first plurality of images at a first machine setting;
determining first alignment differences between a plurality of features on the first plurality of images and corresponding features in layout data corresponding to the first plurality of images;
modeling the first alignment differences using a first modeling;
determining at least one metrology error associated with the first alignment differences;
determining a second machine setting based on the at least one metrology error;
obtaining a second plurality of images at the second machine setting;
determining second alignment differences between a plurality of features on the second plurality of images and corresponding features in layout data corresponding to the second plurality of images;
modeling the second alignment differences using a second modeling; and
adjusting at least one of:
the second machine setting; or
at least one feature of the plurality of features on at least one image of the second plurality of images using the second modeling.

45. A non-transitory computer readable medium that stores a set of instructions that is executable by at least one processor of a computing device to cause the computing device to perform a method for distortion adjustment, the method comprising:
obtaining a first plurality of images at a first machine setting;
determining first alignment differences between a plurality of features on the first plurality of images and corresponding features in layout data corresponding to the first plurality of images;
modeling the first alignment differences using a first modeling;
determining at least one metrology error associated with the first alignment differences;
determining a second machine setting based on the at least one metrology error;
obtaining a second plurality of images at the second machine setting;
determining second alignment differences between a plurality of features on the second plurality of images and corresponding features in layout data corresponding to the second plurality of images;
modeling the second alignment differences using a second modeling; and
adjusting at least one of:
the second machine setting; or
at least one feature of the plurality of features on at least one image of the second plurality of images using the second modeling.

46. A method for distortion adjustment, the method comprising:
obtaining a plurality of images;
determining a plurality of position coordinates, where each position coordinate of the plurality of position coordinates corresponds to a feature of a plurality of features on the plurality of images;
determining a plurality of differences, where each difference of the plurality of differences is between each position coordinate of the plurality of position coordinates and a predetermined position coordinate of a plurality of predetermined position coordinates corresponding to the plurality of features;
modeling the plurality of differences; and
adjusting at least one of:
a machine setting corresponding to obtaining the plurality of images; or
at least one position coordinate corresponding to a feature of the plurality of features using the modeling.

47. The method of clause 46, wherein obtaining the plurality of images further comprises extracting the corresponding machine setting.

48. The method of any one of clauses 46-47, wherein determining the plurality of differences comprises using the corresponding machine setting and the plurality of predetermined position coordinates to align the plurality of position coordinates with the corresponding features in the plurality of predetermined position coordinates.

49. The method of any one of clauses 46-47, wherein modeling the plurality of differences comprises using a model based on the corresponding machine setting.

50. The method of clause 49, wherein the corresponding machine setting comprises a plurality of deflector signal frequencies.

51. The method of clause 49, wherein the model characterizes higher order distortions.

52. The method of clause 49, wherein the model comprises a plurality of models, including at least one model corresponding to a first dimension of the alignment differences and at least one model corresponding to a second dimension of the alignment differences.

53. The method of any one of clauses 46-52, wherein the adjustment is a distortion correction.

54. The method of any one of clauses 46-53, further comprising determining a plurality of metrology errors associated with the plurality of differences and tuning the modeling based on the plurality of metrology errors.

55. The method of any one of clauses 46-54, further comprising extracting a plurality of measurements from the adjusted at least one image.

56. A system for distortion adjustment, the system comprising:
a controller including circuitry configured to cause the system to perform:
obtaining a plurality of images;
determining a plurality of position coordinates, where each position coordinate of the plurality of position coordinates corresponds to a feature of a plurality of features on the plurality of images;
determining a plurality of differences, where each difference of the plurality of differences is between each position coordinate of the plurality of position coordinates and a predetermined position coordinate of a plurality of predetermined position coordinates corresponding to the plurality of features; modeling the plurality of differences; and
adjusting at least one of:
a machine setting corresponding to obtaining the plurality of images; or
at least one position coordinate corresponding to a feature of the plurality of features using the modeling.

57. The system of clause 56, wherein obtaining the plurality of images further comprises extracting the corresponding machine setting.

58. The system of any one of clauses 56-57, wherein determining the plurality of differences comprises using the corresponding machine setting and the plurality of predetermined position coordinates to align the plurality of position coordinates with the corresponding features in the plurality of predetermined position coordinates.

59. The system of any one of clauses 56-57, wherein modeling the plurality of differences comprises using a model based on the corresponding machine setting.

60. The system of clause 59, wherein the corresponding machine setting comprises a plurality of deflector signal frequencies.

61. The system of clause 59, wherein the model characterizes higher order distortions.

62. The system of clause 59, wherein the model comprises a plurality of models, including at least one model corresponding to a first dimension of the alignment differences and at least one model corresponding to a second dimension of the alignment differences.

63. The system of any one of clauses 56-62, wherein the adjustment is a distortion correction.

64. The system of any one of clauses 56-63, wherein the circuitry is further configured to cause the system to perform determining a plurality of metrology errors associated with the plurality of differences and tuning the modeling based on the plurality of metrology errors.

65. The system of any one of clauses 56-64, wherein the circuitry is further configured to cause the system to perform extracting a plurality of measurements from the adjusted at least one image.

66. A non-transitory computer readable medium that stores a set of instructions that is executable by at least one processor of a computing device to cause the computing device to perform a method for distortion adjustment, the method comprising:
obtaining a plurality of images;
determining a plurality of position coordinates, where each position coordinate of the plurality of position coordinates corresponds to a feature of a plurality of features on the plurality of images;
determining a plurality of differences, where each difference of the plurality of differences is between each position coordinate of the plurality of position coordinates and a predetermined position coordinate of a plurality of predetermined position coordinates corresponding to the plurality of features;
modeling the plurality of differences; and
adjusting at least one of:
a machine setting corresponding to obtaining the plurality of images; or
at least one position coordinate corresponding to a feature of the plurality of features using the modeling.

67. The non-transitory computer readable medium of clause 66, wherein obtaining the plurality of images further comprises extracting the corresponding machine setting.

68. The non-transitory computer readable medium of any one of clauses 66-67, wherein determining the plurality of differences comprises using the corresponding machine setting and the plurality of predetermined position coordinates to align the plurality of position coordinates with the corresponding features in the plurality of predetermined position coordinates.

69. The non-transitory computer readable medium of any one of clauses 66-67, wherein modeling the plurality of differences comprises using a model based on the corresponding machine setting.

70. The non-transitory computer readable medium of clause 69, wherein the corresponding machine setting comprises a plurality of deflector signal frequencies.

71. The non-transitory computer readable medium of clause 69, wherein the model characterizes higher order distortions.

72. The non-transitory computer readable medium of clause 69, wherein the model comprises a plurality of models, including at least one model corresponding to a first dimension of the alignment differences and at least one model corresponding to a second dimension of the alignment differences.

73. The non-transitory computer readable medium of any one of clauses 66-72, wherein the adjustment is a distortion correction.

74. The non-transitory computer readable medium of any one of clauses 66-73, wherein the set of instructions that is executable by at least one processor of a computing device to cause the computing device to further perform determining a plurality of metrology errors associated with the plurality of differences and tuning the modeling based on the plurality of metrology errors.

75. The non-transitory computer readable medium of any one of clauses 66-74, wherein the set of instructions that is executable by at least one processor of a computing device to cause the computing device to further perform extracting a plurality of measurements from the adjusted at least one image.

It will be appreciated that the embodiments of the present disclosure are not limited to the exact construction that has been described above and illustrated in the accompanying drawings, and that various modifications and changes may be made without departing from the scope thereof.

1. A system for distortion adjustment, the system comprising:
a controller including circuitry configured to cause the system to perform:
obtaining a plurality of images;
determining alignment differences between a plurality of features on the plurality of images and corresponding features in layout data corresponding to the plurality of images;
modeling the alignment differences; and
adjusting at least one of:
a machine setting corresponding to obtaining the plurality of images; or
at least one feature of the plurality of features on at least one image of the plurality of images using the modeling.

2. The system of claim 1, wherein obtaining the plurality of images further comprises extracting the corresponding machine setting.

3. The system of claim 1, wherein determining the alignment differences comprises using the corresponding machine setting and the layout data to align the plurality of features on the plurality of images with the corresponding features in the layout data.

4. The system of claim 1, wherein modeling the alignment differences comprises using a model based on the corresponding machine setting.

5. The system of claim 4, wherein the corresponding machine setting comprises a plurality of deflector signal frequencies.

6. The system of claim 4, wherein the model characterizes higher order distortions.

7. The system of claim 4, wherein the model comprises a plurality of models, including at least one model corresponding to a first dimension of the alignment differences and at least one model corresponding to a second dimension of the alignment differences.

8. The system of claim 1, wherein the adjustment is a distortion correction.

9. The system of claim 1, wherein the circuitry is further configured to cause the system to perform determining a plurality of metrology errors associated with the alignment differences and tuning the modeling based on the plurality of metrology errors.

10. The system of claim 1, wherein the circuitry is further configured to cause the system to perform extracting a plurality of measurements from the adjusted at least one image.

11. A non-transitory computer readable medium that stores a set of instructions that is executable by at least one processor of a computing device to cause the computing device to perform a method for distortion adjustment, the method comprising:
obtaining a plurality of images;
determining alignment differences between a plurality of features on the plurality of images and corresponding features in layout data corresponding to the plurality of images;
modeling the alignment differences; and
adjusting at least one of:
a machine setting corresponding to obtaining the plurality of images; or
at least one feature of the plurality of features on at least one image of the plurality of images using the modeling.

12. The non-transitory computer readable medium of claim 11, wherein obtaining the plurality of images further comprises extracting the corresponding machine setting.

13. The non-transitory computer readable medium of claim 11, wherein determining the alignment differences comprises using the corresponding machine setting and the layout data to align the plurality of features on the plurality of images with the corresponding features in the layout data.

14. The non-transitory computer readable medium of claim 11, wherein modeling the alignment differences comprises using a model based on the corresponding machine setting.

15. The non-transitory computer readable medium of claim 14, wherein the corresponding machine setting comprises a plurality of deflector signal frequencies.

16. A method for distortion adjustment, the method comprising:
obtaining a plurality of images;
determining alignment differences between a plurality of features on the plurality of images and corresponding features in layout data corresponding to the plurality of images;
modeling the alignment differences; and
adjusting at least one of:
a machine setting corresponding to obtaining the plurality of images; or
at least one feature of the plurality of features on at least one image of the plurality of images using the modeling.

17. The method of claim 16, wherein obtaining the plurality of images further comprises extracting the corresponding machine setting.

18. The method of claim 16, wherein determining the alignment differences comprises using the corresponding machine setting and the layout data to align the plurality of features on the plurality of images with the corresponding features in the layout data.

19. The method of claim 16, wherein modeling the alignment differences comprises using a model based on the corresponding machine setting.

20. The method of claim 19, wherein the corresponding machine setting comprises a plurality of deflector signal frequencies.
